(19) United States
(12) Patent Application Publication
(10) Pub. No.: US 2013/0335956 A1
(43) Pub. Date: Dec. 19, 2013

(54) POLE WITH SOLAR CELL PANELS

(71) Applicants: Steven Scott, Vedbaek (DK); Heine Olsen, Abyhoj (DK); Torben Paaske Christensen, Arhus V (DK)

(72) Inventors: Steven Scott, Vedbaek (DK); Heine Olsen, Abyhoj (DK); Torben Paaske Christensen, Arhus V (DK)

(73) Assignee: SCOTIALIGHT APS, Copenhagen O (DK)

(21) Appl. No.: 14/002,843

(22) PCT Filed: Mar. 3, 2011
(86) PCT No.: PCT/DK2011/000013

§ 371 Date: Sep. 3, 2013

(51) Int. Cl. H01L 31/042; F21S 8/08

(52) U.S. Cl. CPC H01L 31/0422; F21S 8/085
USPC 362/190; 136/251

(57) ABSTRACT

A pole is disclosed having a vertically extending support structure and a plurality of substantially planar solar cell panels for production of electric power, where the solar cell panels are arranged substantially vertically on the support structure. A plurality of holding members fixed to the support structure and extending along vertical edges of said solar cell panels are provided so as to secure the solar cell panels to the support structure, wherein the solar cell panels and the holding members are designed and arranged so that a horizontal clearance of e.g. 3.5 to 10 millimetres is provided along said vertical edges of the solar cell panels so as to allow for wind induced deflection of the support structure with respect to the solar cell panels when the pole is exposed to the environmental wind load.

This is application is National Phase entry of PCT Application number PCT/DK2011/000013 filed on Mar. 3, 2011, the contents of which are hereby incorporated by reference in their entirety.

The present invention relates to a pole having vertically extending solar cell panels for the production of electric power.

### BACKGROUND

Solar cell panels arranged on poles, in particular on lamp posts, have been described in various documents. In some embodiments, the solar cell panels are arranged on carrier surfaces so that they have an advantageous angle to the incoming sun light, and in other embodiments, the solar cell panels are arranged substantially vertically and are more or less an integrated part of the pole, so that the visual impression of the pole deviates less from other poles.

One example is given in the U.S. Pat. No. 6,060,658 which discloses a pole incorporating solar cells having a lighting device or like electric device attached thereto, and a required number of planar solar cell modules arranged approximately vertically on at least one portion of peripheral wall of the main body of the pole. The arrangement of solar cell modules has the function of generating the electric energy to be consumed by the electric device for one day, utilizing solar radiation afforded by scattered or direct sunlight. A storage device is provided in the pole main body and has a capacity to accumulate therein the electric energy to be consumed by the electric device for one day, and is repeatedly charged and discharged every day. The solar cell modules are secured to the main body of the pole by elongated corner members provided with groves for holding the modules or alternatively arranged to clamp the modules to the main body.

It is an object of the present invention to provide a pole having solar cells which is of a design that allows for a taller and/or lighter construction of the pole. Other advantages of the present invention will be clear from the description provided below.

### BRIEF DESCRIPTION OF THE INVENTION

With the present invention is provided a pole having a vertically extending support structure, a plurality of substantially planar solar cell panels for production of electric power, where the solar cell panels are arranged substantially vertically on the support structure, and a plurality of holding members fixed to the support structure and extending along vertical edges of said solar cell panels so as to secure the solar cell panels to the support structure, wherein the solar cell panels and the holding members are designed and arranged so that a horizontal clearance is provided along said vertical edges of the solar cell panels so as to allow for wind induced deflection of the support structure with respect to the solar cell panels when the pole is exposed to the environmental wind load. The wind load may be calculated from the relevant norms available relating to the art, such as the European Norm EN 40-3-1:2000 Lighting columns. Design and verification. Specification for characteristic loads.

The solar cell panels are normally of the laminated type constructed from a number of photovoltaic cells arranged on a plane carrying structure made from glass, which is brittle and only allows for minor deformations in the plane in which it extends. Thus, in case the solar cell panels are fixed to the support structure, any possible significant deformation of the pole due to the wind load on the pole will apply a stress on the panels which outer surface extend in the direction of the deflection and may cause them to break.

By providing the horizontal clearance along the vertical edges of the solar cell panels and allowing the support structure to deflect relatively to the solar cell panels, it is made possible to construct the pole so that a significant deflection thereof due to environmental wind load will be allowable and thus provide for a lighter construction of the support structure and/or a taller construction of the pole.

The wind load on the pole and the resulting deflection thereof may be found by applying standard techniques known within structural engineering. The design wind speed and wind shear distribution may vary at different geographical locations, but the skilled person will be able to determine the environmental wind load and the deflection of a construction, e.g. for general urban conditions.

It is in one embodiment preferred that the clearance along the vertical edges of at least some of the solar cell panels, i.e. the panels arranged where the curvature of the pole due to wind induced deflection is at a maximum, has a horizontal extent of at least 2 millimetres, such as in the range of 2 to 12 millimetres, preferably of at least 3.5 millimetres, such as in the range of 3.5 to 10 millimetres, and most preferred of at least 5 millimetres.

According to an alternative embodiment, the horizontal extent of the clearance along the vertical edges of at least some of the solar cell panels is determined from the vertical extent of the solar cell panel as the need for clearance is proportional to the vertical extent of the solar cell panel. Thus, the horizontal extent of the clearance is at least 1 part per thousand, such as in the range of 1 to 7 parts per thousand, preferably of at least 2 parts per thousand, such as in the range of 2 to 6 parts per thousand, and most preferred of at least 3 parts per thousand of the vertical extent of the solar cell panel.

The vertically extending support structure comprises in a preferred embodiment an extruded profile and is most preferably mainly constituted by an extruded profile. An extruded profiled is characterised in being a profile with constant cross-section and therefore constant mechanical properties throughout the length of the structure. Extrusion is a cost-efficient method of producing in particular aluminium profiles, which are preferred in the present invention. By the term extruded profile is herein also understood a pultruded profile of a composite material of reinforcement fibres, such as glass fibres, carbon fibres or natural fibres in a matrix of a thermosetting or thermoplastic resin.

In an alternative embodiment to the extruded profile the support structure may be manufactured from profiles of pressed steel sheet.

It is preferred that the solar cell panels are secured to the extruded profile by means of the holding members, i.e. that the part of the support structure that the solar cell panels are secured to is constituted by the extruded profile.

The extruded profile has preferably a vertical extent of at least 6 meters, preferably at least 8 meters, and most preferred at least 10 meters. In one embodiment, the extruded profile is placed on top of a base structure extending e.g. 1.5 to 2.5 meters above the ground and preferably being manufactured from an impact-resistant material such as steel or concrete.

The holding force fixing the solar cell panels to the support structure may be provided by separate elements such as clips, tape or a flexible strip enclosing the edges of the solar cell panel and having parts that can be fixed to the support structure by means of e.g. screws, and the holding members have the function of protecting the edges of the solar cell panels and in particular to secure the solar cell panels so that they do not become detached from the support structure, which could cause accidents in particular when the pole is erected in an urban area. It is however preferred that the solar cell panels are fixed to support structure the by means of holding members so that they are arranged to clamp the edges of the solar cell panels to the support structure.

The pole is according to one preferred embodiment of a generally square cross section. In an alternative embodiment, the pole is of a generally triangular cross section with dummy panels (panels without solar cells thereon) arranged on the side facing north. Another feasible cross section could be pentagonal again with dummy panels facing north. In regions near the equator, where the sun passes very close to zenith most of the year, solar cell panels facing either north or south will produce little electrical power and a cross sectional shape of the pole being rectangular with the longer sides carrying solar cell panels facing east and west or a rhomb shaped cross section carrying solar cell panels on all four sides and with the obtuse angles facing east and west so as to optimize the solar radiation on the solar cell panels.

The horizontal extent of the solar cell panels is preferably within the range of 130 to 220 millimetres, more preferably within the range of 160 to 190 millimetres.

The vertical extend of the solar cell panels is preferably at least 15 centimetres or 6 inches.

The holding members are preferably made from extruded profiles, in particular made from aluminium.

At least some of the holding members may be arranged to enclose a corner of the support structure so that the holding members secure solar cell panels on both sides of the corner to the support structure.

It is particularly advantageous that the holding members and the solar cell panels are so designed and arranged that the vertical edges of the solar cell panels each are secured by one of said holding members only. Hereby, the operation of removing and replacing a single solar cell panel is simplified in that it is sufficient to remove the two holding members that secure the vertical edges of the solar cell panel to the support structure and the possible covers that are arranged to cover the horizontal edges in order to remove a solar cell panel.

Likewise it is preferred that the holding members are arranged so that they in a longitudinal direction of the pole secure the vertical edge of one solar cell panel only. Thus, the holding member may secure two solar cell panels arranged next to each other in the horizontal level, in particular when the holding member secures solar cell panels on both sides of a corner to the support structure, but the holding members do not extend across two solar cell panels or more in the longitudinal direction of the pole. Hereby, the removal and replacement of a single solar cell panel is simplified in that the loosening or removal of a holding member that secures the solar cell panel will not affect the securing of the solar cell panels above or below the panel to be removed, and the neighbouring solar cell panels in the same horizontal level will still be secured at their opposite vertical edge and will thus not be loosened from the pole.

It is advantageous that a layer of a flexible material, preferably an elastic material such as a natural or artificial rubber or silicone rubber or another elastomer, is provided between the holding members and the corresponding solar cell panel. The flexible or elastic material makes it in particular more feasible to apply a clamping pressure from the holding member on the solar cell panels without causing damage to the panels and the flexible material will facilitate the relative movement between the holding member and the solar cell panel during deflections of the support structure.

It is particularly advantageous that said layer of a flexible material is a part of a U-shaped strip enclosing the vertical edge of the solar cell panel, so that a layer of the flexible or elastic material is provided between the support structure and the solar cell panel, which further enhances the advantages and also provide for the relative movement between the support structure and the solar cell panel during deflections of the support structure.

At least some of the solar cell panels are in a preferred embodiment provided with a flexible attachment to the support structure so as to bias the solar cell panel towards an initial position in the horizontal direction. The flexible attachment could be in the form of a length of a flexible film provided with an adhesive on one side, such as adhesive tape, which is applied to one side surface of the solar cell panel as well as to a part of the support structure. Hereby a possible migration of the solar cell panel over time due to repeated deflections of the support structure with respect to the solar cell panels is prevented and consequently a reduction over time of the magnitude of the clearance along one of the vertical side edges will be prevented.

A vertical ventilation cavity is preferably provided between the solar cell panels and the support structure to ensure that the solar cell panels are not heated excessively which may lead to shortening of the life time of the photovoltaic cells of the solar cell panels. The depth (D) of the cavity is preferably at least 10 millimetres, more preferably at least 15 millimetres, and the depth (D) of the cavity is in an advantageous embodiment within the range of 10 to 75 millimetres, preferably within the range of 15 to 50 millimetres.

According to another embodiment, the horizontal extent of the cavity parallel to the solar cell panel is at least half of the horizontal extent of the solar cell panel.

The pole may further comprise a street lightning device. However, the pole may be used for supporting other relevant items, such as traffic signs, telecommunication transmitters, wireless data communication transmitters, surveillance cameras and/or warning lights.

### BRIEF DESCRIPTION OF THE DRAWING

An embodiment of the present invention will in the following be described with reference to the drawing in which

FIG. 1 illustrates a side view of the pole with solar cell panels and a street lighting device, when the pole is not deflected by wind loads,

FIG. 2 illustrates a cross-sectional view of the pole,

FIG. 3 illustrates a side view of the pole with solar cell panels and a street lighting device, when the pole is exposed to wind loads with a resulting deflection,

FIG. 4 illustrates a solar cell panel with U-shaped strips enclosing its vertical edges, and

FIG. 5 illustrates an enlarged part of the cross-sectional view of FIG. 2 of the pole, showing in particular the horizontal clearance.

### DESCRIPTION OF AN EMBODIMENT OF THE INVENTION

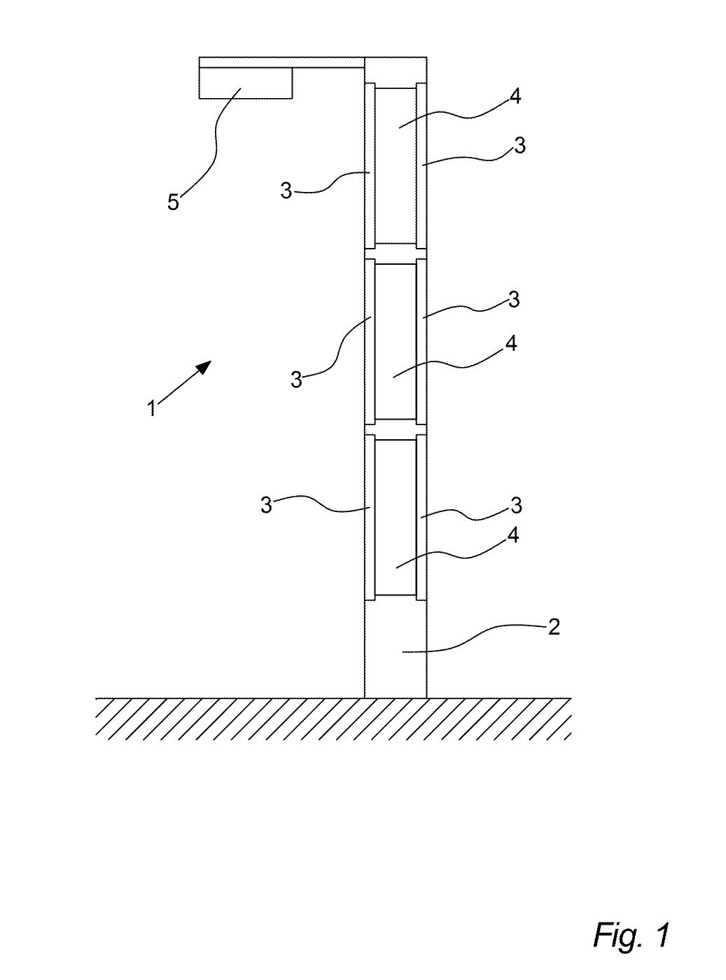

Referring to FIG. 1, a pole 1 for mounting solar cell panels is shown. The pole 1 comprises a vertically extending support structure 2 in the form of an extruded aluminium profile, a plurality of substantially planar solar cell panels 4, a plurality of corner holding members 3, and a street lighting device 5. These solar cell panels 4 are arranged substantially vertically on the support structure 2. Furthermore, corner holding members 3 in the form of extruded aluminium profiles are arranged to enclose the corners of the support structure 2 so as to clamp the solar cell panels 4 to the support structure 2. In an alternative embodiment, the support structure 2 is placed on top of a base structure extending e.g. 1.5 to 2.5 meters above the ground and being manufactured from an impact-resistant material such as steel or concrete.

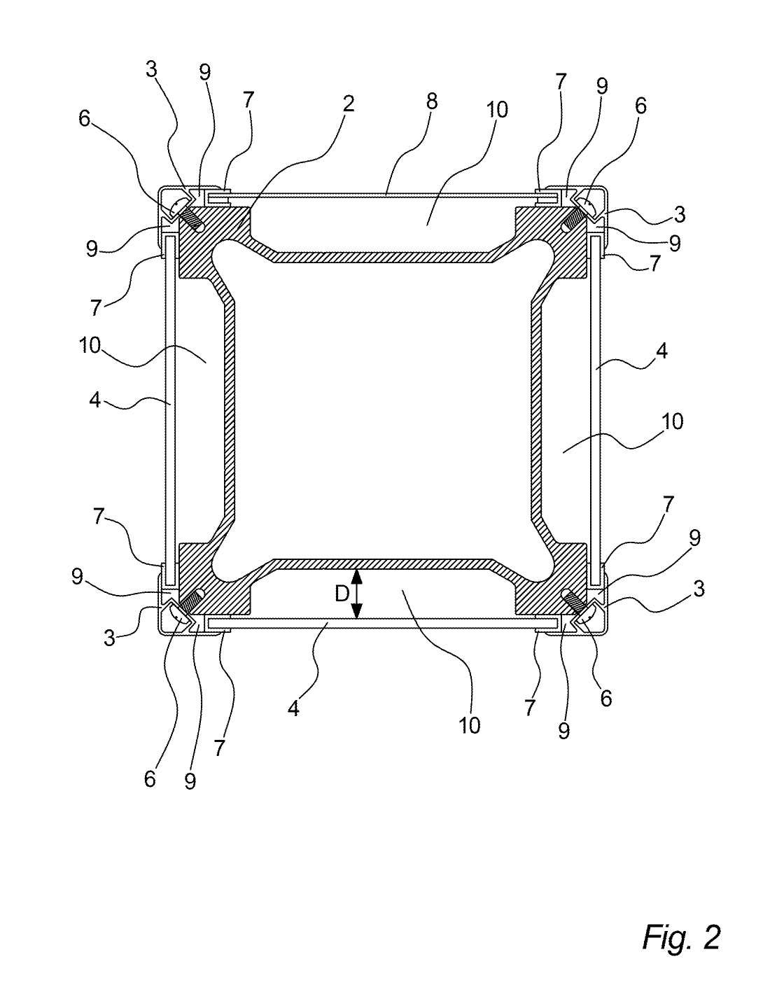

Referring to FIG. 2, a cross section view of the pole 1 is shown. The solar cell panels 4 are fitted with U-shaped strips 7 of silicone rubber, so that said U-shaped strips 7 enclose the vertical edges of the solar cell panels 4. As the corner holding members 3 are arranged along the vertical edges of the solar cell panels 4, said corner holding members 3 clamp onto the U-shaped strips 7. Thus, one arm of the U-shaped strips 7 is arranged between the solar cell panel 4 and the support structure 2 and the other arm of the strip 7 is provided between the solar cell panel 4 and the corner holding member 3. A solar cell panel 4 with U-shaped strips 7 is clamped to the support structure 2 by corner holding members 3 and holding member screws 6 on three of the four sides of the support structure 2. As an alternative to the use of screws 6, the holding members may be attached to the support structure 2 by means of a clip-on system. Each corner holding member 3 simultaneously clamps two horizontally adjacent solar cell panels 4 to the support structure 2. The corner holding members 3 allows for access to a holding member screw 6 through an opening [not shown] in said corner holding member 3 made after extrusion of said corner holding member 3. Furthermore, the solar cell panels 4 are fixed to the support structure 2 by elastic fastening means [not shown] in the form of an elastic tape with adhesive on one side.

Similarly, a north-side panel 8 and U-shaped strips 7 are clamped to the support structure 2 by corner holding members 3 and holding member screws 6 on the fourth side of said support structure 2 arranged so that the panel 8 is facing north where the lack of incoming sunlight at least at locations to the north makes the provision of a solar cell panel 4 worthless. Of course, when situated at locations south of the Equator, the side would be facing south instead.

The solar cell panels 4 and corner holding members 3 are designed and arranged so that a horizontal clearance 9 is provided along the vertical edge of the solar cell panels 4, between said solar cell panel 4 and the corner holding member 3.

Behind each of the solar cell panels 4 as well as the north panel 8 is a vertical ventilation cavity 10 with a depth D.

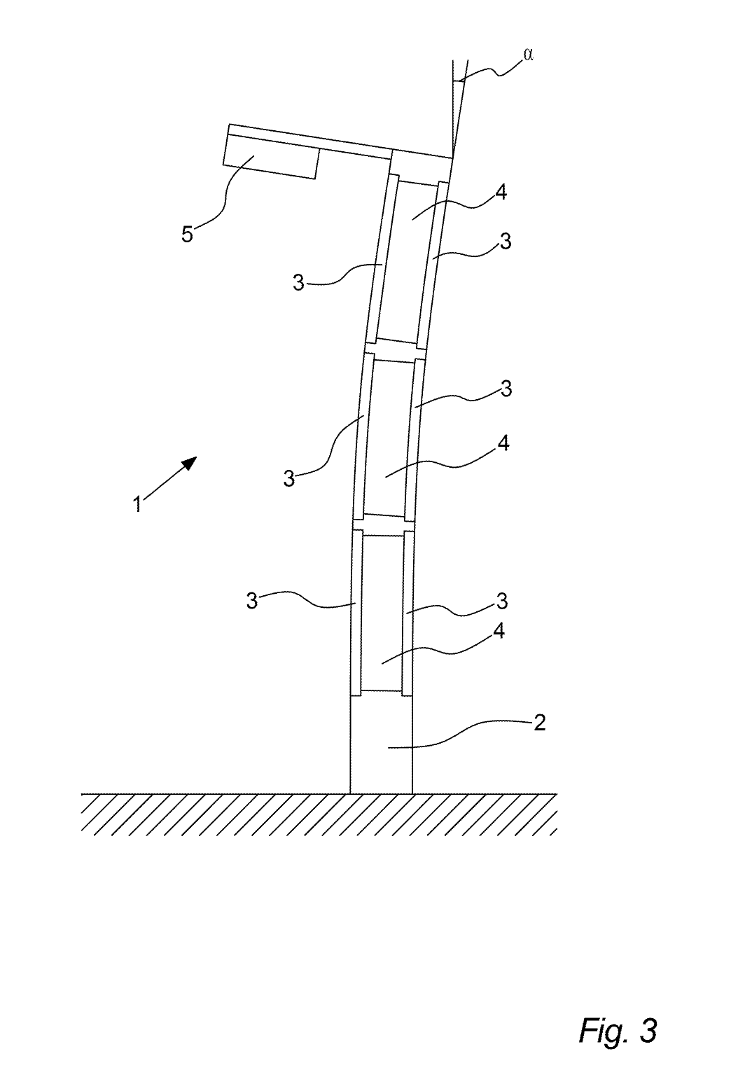

Referring to FIG. 3, the pole 1 of FIG. 1 4 is shown. The pole 1 is exposed to environmental wind load and a wind induced deflection of the support structure 2 is shown, represented by the deflection angle . In order to make the deflection angle clearly visible, the magnitude of the deflection angle has been exaggerated.

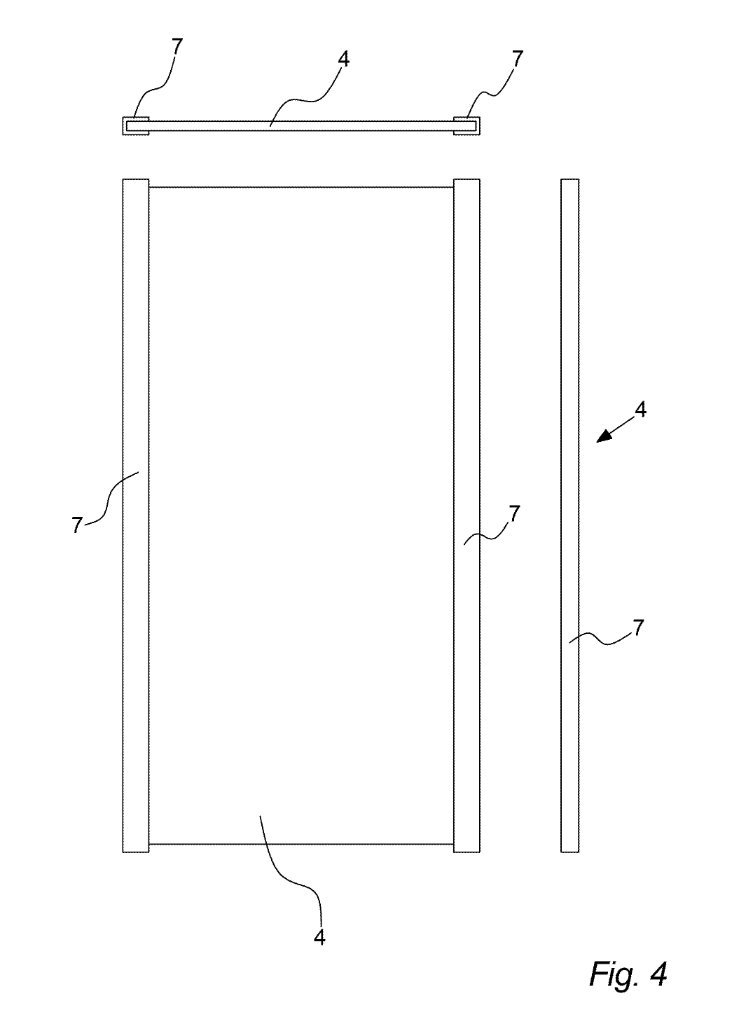

On FIG. 4 a solar cell panel 4 is shown in three different views, front, side, and top view. U-shaped strips 7 are enclosing the vertical edges of the solar cell panels 4.

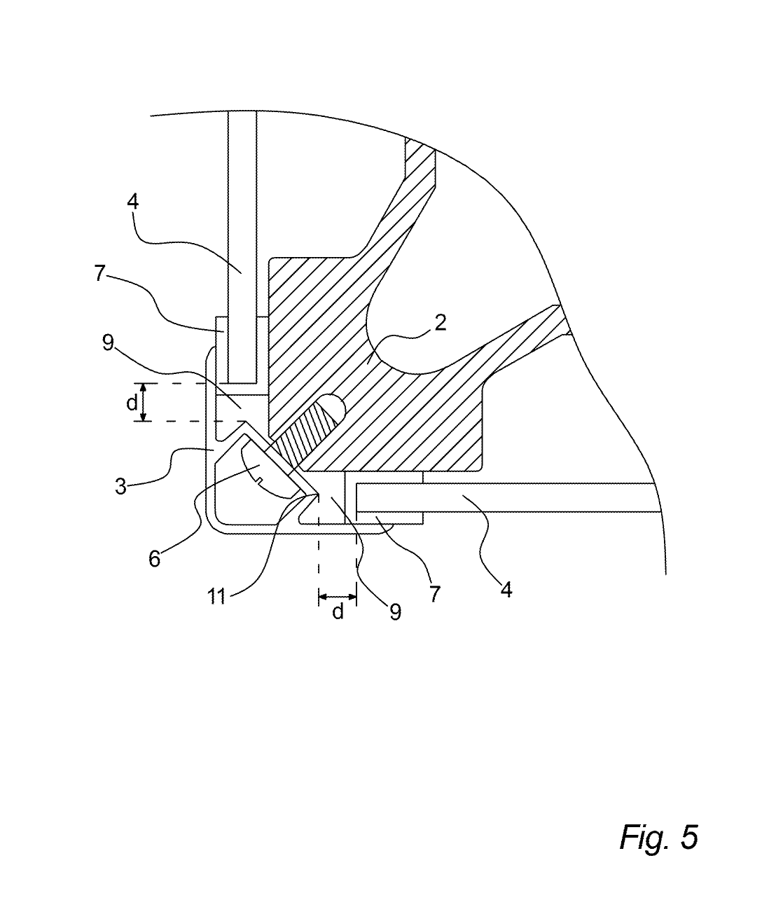

On FIG. 5 a close-up of a part of the cross-sectional view of the pole 1 is shown. Parts of two solar cell panels 4 with U-shaped strips 7 enclosing the vertical edges of said solar cell panel 4 are shown. The solar cell panels 4 and U-shaped strips 7 are clamped to the support structure 2 by holding member 3 and holding member screw 6. The horizontal clearance 9 of magnitude d between the vertical edge of the solar cell panel 2 and the corner holding member 3 is clearly shown. The magnitude d of the horizontal clearance 9 is in the present embodiment 6 millimetres for solar cell panels of a vertical extend of about 1700 millimetres.

The solar cell panels 4 are clamped by the corner holding members 3 in such a way that relative movement between the support structure 2 and said solar cell panel 4 is restricted in the direction normal to the surface of said solar cell panel 4, apart from the movement allowed by the U-shaped strips 7. In the horizontal direction parallel to the surface of the solar cell panel 4, the movement of the support structure 2 relatively to the solar cell panel 4 is not completely restricted, since a horizontal clearance 9 is provided along each of the vertical edges of said solar cell panel 4. This is shown in both FIGS. 2 and 5. The total width of the solar cell panel 4 with U-shaped strips 7 enclosing the vertical edges of said solar cell panels 4 is therefore 2d less than the distance between the corners 11 of the two holding members 3 clamping said solar cell panel 4. That means, that the support structure 2 may be deflected by a magnitude of d in any direction perpendicularly to a solar cell panel 4 by the wind load over the vertical extend of a solar cell panel 4 without causing damage to any o the solar cell panels 4. The elastic fastening means in the form of an elastic tape will tend to bring solar cell panel 4 back to the centre position in middle of the spacing between the two corners 11 of the two holding members 3 clamping said solar cell panel 4 and thereby prevent migration of the solar cell panels 4 over time towards one of the corner holding members 3.

The deflection of the support structure 2 will cause the solar cell panel 4 to deflect correspondingly if said deflection of said support structure 2 is in a direction normal to the surface of said solar cell panel 4, since said solar cell panel 4 is clamped by the holding members 3, and relative movement in this direction is. However, if the deflection of the support structure 2 is in a direction parallel to the surface of the solar cell panel 4, said solar cell panel 4 is allowed some relative movement with respect to the support structure 2, because displacement in the horizontal clearance 9 is only elastically restricted. Thus, the horizontal clearance 9 allows for a deflection of the support structure 2 without corresponding deflection of the solar cell panels 4 in the direction parallel to the surface of the solar cell panels 4, which for a brittle glass plate of a solar cell panel 4 can be destructive.

To remove a solar cell panel 4 for cleaning, repair, or replacement one must first remove the two corner holding members 3 clamping said solar cell panel 4. When this is done the solar cell panel 4 can readily be removed. This leaves the two adjacent solar cell panels 4 in a state where they are only clamped by a single corner holding member 3. This is at least temporarily sufficient to keep the solar cell panels 4 in place. This way the solar cell panels 4 can be removed separately.

Further aspects of the invention include:

1. A pole according to any of claims 1-3, wherein the vertically extending support structure comprises an extruded profile.

2. A pole according to aspect 1, wherein the extruded profile is an aluminium profile.

3. A pole according to aspects 1 or 2, wherein the solar cell panels are secured to the extruded profile by means of the holding members.

4. A pole according to any of aspects 1-3, wherein the extruded profile has a vertical extent of at least 6 meters, preferably at least 8 meters, and most preferred at least 10 meters.

5. A pole according to any of claims 1-4 and aspects 1-4, wherein the pole is of a generally square cross section.

6. A pole according to any of claims 1-4 and aspects 1-4, wherein the pole is of a generally triangular cross section.

7. A pole according to any of claims 1-4 and aspects 1-6, wherein the horizontal extent of the solar cell panels is within the range of 130 to 220 millimetres, preferably in the range of 160 to 190 millimetres.

8. A pole according to any of claims 1-4 and aspects 1-7, wherein the vertical extend of the solar cell panels is at least 15 centimetres.

9. A pole, wherein the holding members are made from extruded profiles and wherein the holding members are made from aluminium.

### REFERENCE NUMERALS

1. Pole
2. Vertically extending support structure
3. Corner holding member
4. Solar cell panel
5. Street lighting device
6. Holding member screw
7. U-shaped strip
8. North panel
9. Horizontal clearance
10. Vertical ventilation cavity
α Angle of deflection
d Magnitude of horizontal clearance

1. A pole, comprising:
a vertically extending support structure;
a plurality of substantially planar solar cell panels for production of electric power, wherein the solar cell panels are arranged substantially vertically on the support structure; and
a plurality of holding members fixed to the support structure and extending along vertical edges of said solar cell panels so as to secure the solar cell panels to the support structure, wherein the solar cell panels and the holding members are designed and arranged so that a horizontal clearance is provided along said vertical edges of the solar cell panels so as to allow for wind induced deflection of the support structure with respect to the solar cell panels when the pole is exposed to the environmental wind load, and the horizontal clearance allowing for a deflection of the support structure without corresponding deflection of the solar cell panels in a direction parallel to the surface of the solar cell panels.

2. A pole according to claim 1, wherein said clearance along said vertical edges of at least some of the solar cell panels has a horizontal extent being any one of at least 2 millimetres, at least 3.5 millimetres, at least 5 millimetres, in the range of 2 to 12 millimetres, and in the range of 3.5 to 10 millimetres.

3. (canceled)

4. A pole according to claim 1, wherein the clearance has a horizontal extent being any one of at least 1 part per thousand, at least 2 parts per thousand, least 3 parts per thousand, in the range of 1 to 7 parts per thousand, and in the range of 2 to 6 parts per thousand of the vertical extent of the solar cell panel.

5-9. (canceled)

10. A pole according to claim 1, wherein said plurality of holding members clamp the solar cell panels to the support structure.

11-14. (canceled)

15. A pole according to claim 1, wherein the holding members are made from extruded profiles.

16. (canceled)

17. A pole according to claim 1, wherein at least some of the holding members are arranged to enclose a corner of the support structure and secure solar cell panels on both sides of the corner to the support structure.

18. A pole according to claim 1, wherein the vertical edges of the solar cell panels each are secured by one of said holding members only.

19. A pole according to claim 1, wherein the holding members are arranged so that they in a longitudinal direction of the pole secure the vertical edge of one solar cell panel only.

20. A pole according to claim 1, wherein a layer of a flexible material is provided between the holding members and the corresponding solar cell panel.

21. A pole according to claim 20, wherein said layer of a flexible material is a part of a U-shaped strip enclosing the vertical edge of the solar cell panel.

22. A pole according to claim 1, wherein at least some of the solar cell panels are provided with a flexible attachment to the support structure so as to bias said solar cell panels toward an initial position in the horizontal direction.

23. A pole according to claim 1, wherein a vertical ventilation cavity is provided between the solar cell panels and the support structure.

24. A pole according to claim 23, wherein the depth of the cavity is any one of at least 10 millimetres, at least 15 millimetres, within the range of 10 to 75 millimetres, and within the range of 15 to 50 millimetres.

25. (canceled)

26. A pole according to claim 23, wherein the horizontal extent of the cavity parallel to the solar cell panel is at least half of the horizontal extent of the solar cell panel.

27. A pole according to claim 1, further comprising a street lightning device.
